(19) United States
(12) Patent Application Publication
(10) Pub. No.: US 2024/0243193 A1
(43) Pub. Date: Jul. 18, 2024

(54) SEMICONDUCTOR DEVICE

(71) Applicant: SUMITOMO ELECTRIC DEVICE INNOVATIONS, INC., Kanagawa (JP)

(72) Inventor: Hiroaki MARUYAMA, Kanagawa (JP)

(21) Appl. No.: 18/397,252

(22) Filed: Dec. 27, 2023

(30) Foreign Application Priority Data
Jan. 13, 2023 (JP) 2023-004022

(51) Int. Cl. H01L 29/778; H01L 29/20

(52) U.S. Cl. CPC H01L 29/7781; H01L 29/2003

(57) ABSTRACT

A semiconductor device of the present disclosure includes a substrate; a buffer layer above the substrate; a barrier layer on the buffer layer; an electron traveling layer on the barrier layer; and an electron supply layer above the electron traveling layer. The electron traveling layer is thinner than the buffer layer. A band gap of the barrier layer is larger than a band gap of the buffer layer and a band gap of the electron traveling layer.

### CROSS-REFERENCE TO RELATED APPLICATIONS

This application is based on and claims priority to Japanese Patent Application No. 2023-004022, filed on Jan. 13, 2023, the entire contents of which are incorporated herein by reference.

### TECHNICAL FIELD

The present disclosure relates to semiconductor devices.

### BACKGROUND

An increase in transient response performance is desired in semiconductor devices with a high electron mobility transistor (HEMT) containing gallium nitride (GaN). See, for example, Japanese Laid-open Patent Application Publication Nos. 2019-121785 and 2015-095605.

### SUMMARY

A semiconductor device of the present disclosure includes: a substrate; a buffer layer above the substrate; a barrier layer on the buffer layer; an electron traveling layer on the barrier layer; and an electron supply layer above the electron traveling layer. The electron traveling layer is thinner than the buffer layer. A band gap of the barrier layer is larger than a band gap of the buffer layer and a band gap of the electron traveling layer.

### BRIEF DESCRIPTION OF DRAWINGS

FIG. 1 is a cross-sectional view illustrating a semiconductor device according to an embodiment.

FIG. 2 is a band diagram illustrating a band structure of a buffer layer, a barrier layer, an electron traveling layer, a spacer layer, an electron supply layer, and a cap layer in the embodiment.

FIG. 3 is a cross-sectional view illustrating a semiconductor device according to a reference example.

FIG. 4 is a band diagram illustrating a band structure of an electron traveling layer, a spacer layer, an electron supply layer, and a cap layer in the reference example.

### DETAILED DESCRIPTION

A conceivable way of increasing transient response performance is to make an electron traveling layer thin. However, when the electron traveling layer is made thin, there is possibility of reduction in crystallinity of a channel region and an electron supply layer. Such reduction in crystallinity can lead to degradation in characteristics of electron mobility and the like.

It is an objective of the present disclosure to provide a semiconductor device that can be increased in transient response performance while avoiding reduction in crystallinity.

According to the present disclosure, it is possible to increase transient response performance while avoiding reduction in crystallinity.

### Description of Embodiments of the Present Disclosure

First, embodiments of the present disclosure will be listed and described.
[1] A semiconductor device according to one embodiment of the present disclosure includes: a substrate; a buffer layer above the substrate; a barrier layer on the buffer layer; an electron traveling layer on the barrier layer; and an electron supply layer above the electron traveling layer, in which the electron traveling layer is thinner than the buffer layer, and a band gap of the barrier layer is larger than a band gap of the buffer layer and a band gap of the electron traveling layer.

Because the band gap of the barrier layer is larger than the band gap of the buffer layer and the band gap of the electron traveling layer, negative polarization charges are present near the interface between the barrier layer and the electron traveling layer, and positive polarization charges are present near the interface between the barrier layer and the buffer layer. Also, in the electron traveling layer, the lower end of the conduction band is higher at a position closer to the barrier layer. Therefore, even if electrons in two-dimensional electron gas have high energy, the negative polarization charges prevent movement of the electrons in two-dimensional electron gas toward a deep position in the electron traveling layer. Therefore, even if a trap level is present in the electron traveling layer, the electrons are not readily trapped at the trap level, and it is possible to suppress reduction in transient response performance due to the trap of the electrons. Also, because the barrier layer can increase transient response performance, the buffer layer does not need to be made thin to an extent of causing reduction in crystallinity. Therefore, it is possible to increase transient response performance while avoiding reduction in crystallinity.
[2] In [1], both of the buffer layer and the electron traveling layer may be a GaN layer, and the barrier layer may be an AlₓIn_{y}Ga_{1-x-y}N layer (0<x≤1, 0≤y≤0.1). In this case, the band gap of the barrier layer more readily becomes larger than the band gap of the buffer layer and the band gap of the electron traveling layer.
[3] In [2], a relation of “y+0.8≤x” may be established. In this case, polarization charges are more readily sufficiently obtained.
[4] In any one of [1] to [3], a thickness of the barrier layer may be 2 nm or larger and 20 nm or smaller. When the thickness of the barrier layer is 2 nm or larger, polarization charges are more readily sufficiently obtained. When the thickness of the barrier layer is 20 nm or smaller, the barrier layer is more readily pseudo-lattice matched with the buffer layer.
[5] In any one of [1] to [4], a thickness of the buffer layer may be 200 nm or larger. When the thickness of the buffer layer is 200 nm or larger, favorable crystallinity is more readily obtained.
[6] In any one of [1] to [5], a thickness of the electron traveling layer may be 400 nm or smaller. When the thickness of the electron traveling layer is 400 nm or smaller, the entirety of the electron traveling layer is more readily influenced by the polarization charges.

### Details of Embodiments of the Present Disclosure

Hereinafter, embodiments of the present disclosure will be described in detail, but the present disclosure should not be construed as being limited to these. Note that, in the present specification and the drawings, components having substantially the same functional configuration are given the same reference symbol, and description thereof may be omitted.

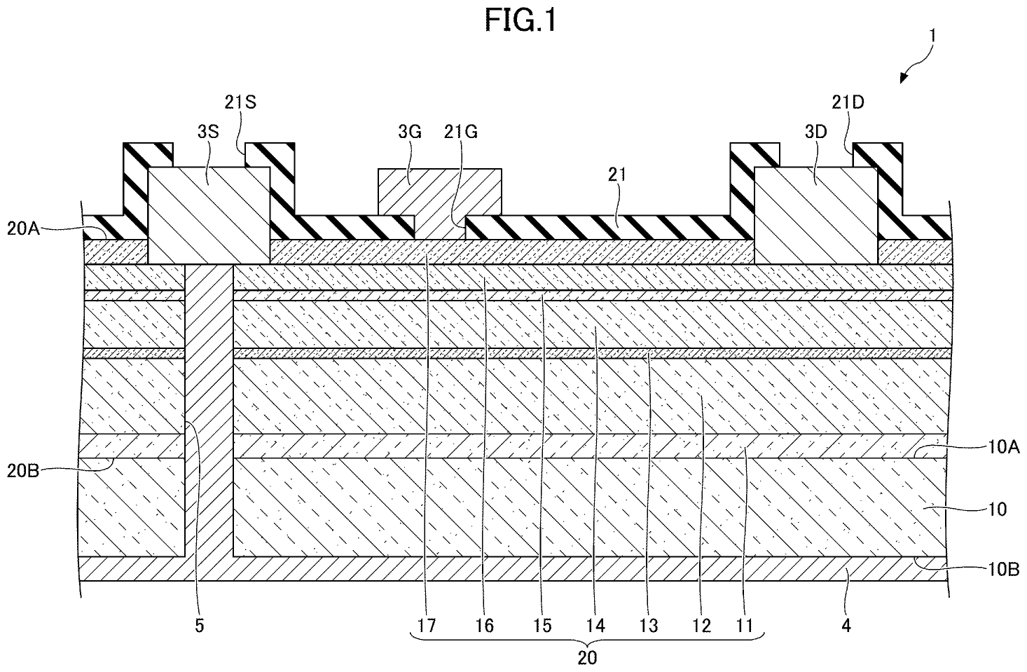

The embodiments relate to semiconductor devices including a gallium nitride-based high electron mobility transistor (GaN-HEMT) containing a nitride semiconductor as a main constituent material. FIG. 1 is a cross-sectional view illustrating a semiconductor device according to the embodiment.

As illustrated in FIG. 1, a semiconductor device 1 according to the embodiment includes a substrate 10, a stacked structure 20 of a plurality of semiconductor layers formed on or above the substrate 10, a gate electrode 3G, a source electrode 3S, a drain electrode 3D, and a rear-surface electrode 4. The substrate 10 includes an upper surface 10A and a lower surface 10B opposite to the upper surface 10A. The substrate 10 is, for example, a silicon carbide (SiC) substrate in which the plane orientation of the upper surface 10A is a (0001) plane. The stacked structure 20 is provided on the substrate 10. The stacked structure 20 includes an upper surface 20A and a lower surface 20B opposite to the upper surface 20A. The lower surface 20B is in direct contact with the upper surface 10A. The stacked structure 20 includes an initial layer 11, a buffer layer 12, a barrier layer 13, an electron traveling layer 14, a spacer layer 15, an electron supply layer 16, and a cap layer 17.

The initial layer 11 is provided on the substrate 10. The initial layer 11 is, for example, an aluminum nitride (AlN) layer having a thickness of 5 nm or larger and 100 nm or smaller. The buffer layer 12 is provided on the initial layer 11. The buffer layer 12 is, for example, an undoped gallium nitride (GaN) layer having a thickness of 200 nanometers (nm) or larger and 20 micrometers (μm) or smaller. The barrier layer 13 is provided on the buffer layer 12. The barrier layer 13 is, for example, an undoped AlN layer having a thickness of 2 nm or larger and 20 nm or smaller. The electron traveling layer 14 is provided on the barrier layer 13. The electron traveling layer 14 is, for example, an undoped GaN layer having a thickness of 200 nm or larger and 400 nm or smaller. The spacer layer 15 is provided on the electron traveling layer 14. The spacer layer 15 is an undoped aluminum gallium nitride (AlGaN) layer having a thickness of 2 nm or larger and 10 nm or smaller. The electron supply layer 16 is provided on the spacer layer 15. The electron supply layer 16 is, for example, a n-type AlGaN layer having a thickness of 5 nm or larger and 28 nm or smaller. The sum of the thickness of the spacer layer 15 and the thickness of the electron supply layer 16 is, for example, 10 nm or larger and 30 nm or smaller. The cap layer 17 is provided on the electron supply layer 16. The cap layer 17 is, for example, a n-type GaN layer having a thickness of 1 nm or larger and 10 nm or smaller. The electron supply layer 16 and the cap layer 17 contain silicon (Si), germanium (Ge), or the like, as a n-type impurity. The stacking direction of the initial layer 11, the buffer layer 12, the barrier layer 13, the electron traveling layer 14, the spacer layer 15, the electron supply layer 16, and the cap layer 17 is, for example, the direction of SiC forming the substrate 10.

In the present embodiment, the electron traveling layer 14 is thinner than the buffer layer 12. Also, the band gap of the barrier layer 13 is larger than the band gap of the buffer layer 12 and the band gap of the electron traveling layer 14.

The source electrode 3S and the drain electrode 3D are formed on the electron supply layer 16. The source electrode 3S and the drain electrode 3D are in contact with the upper surface of the electron supply layer 16. The source electrode 3S and the drain electrode 3D are in Ohmic contact with the electron supply layer 16.

An insulating film 21 is formed on the cap layer 17. The insulating film 21 is, for example, a silicon nitride (SiN) film. The insulating film 21 covers the source electrode 3S and the drain electrode 3D. Openings 21S, 21G, and 21D are formed in the insulating film 21. The source electrode 3S is exposed from the opening 21S, and the drain electrode 3D is exposed from the opening 21D. The opening 21G is formed between the source electrode 3S and the drain electrode 3D. The gate electrode 3G is formed on the insulating film 21 between the source electrode 3S and the drain electrode 3D, and contacts the upper surface 20A of the stacked structure 20 through the opening 21G. The gate electrode 3G is in Schottky contact with the stacked structure 20. The opening 21G and the gate electrode 3G may be closer to the source electrode 3S than to the drain electrode 3D.

A through-hole 5 is formed in the substrate 10 and the stacked structure 20. The through-hole 5 penetrates the substrate 10 and the stacked structure 20, and reaches the source electrode 3S. The rear-surface electrode 4 is formed on the lower surface 10B of the substrate 10. The rear-surface electrode 4 is in contact with the lower surface 10B, and is in contact with the source electrode 3S via the through-hole 5. The source electrode 3S and the rear-surface electrode 4 are electrically connected to each other. If the source electrode 3S and the rear-surface electrode 4 are electrically connected to each other, the through-hole 5 may be formed at a position apart from the source electrode 3S, and the rear-surface electrode 4 may be in no direct contact with the source electrode 3S.

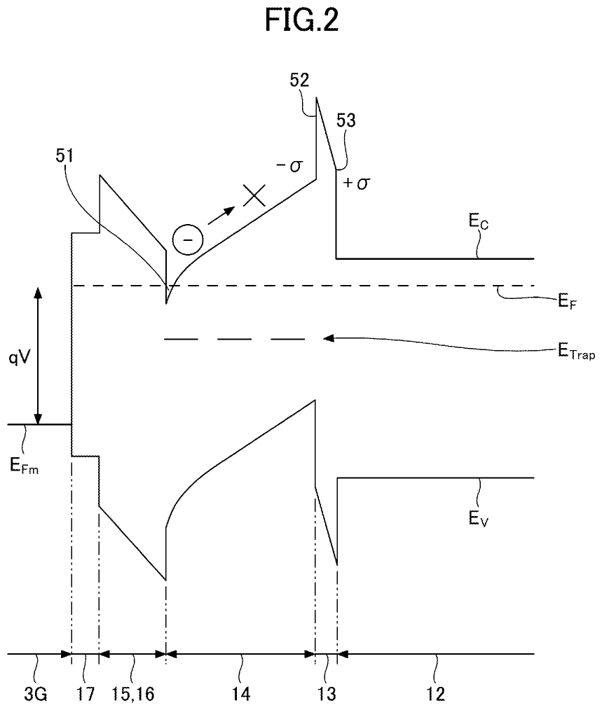

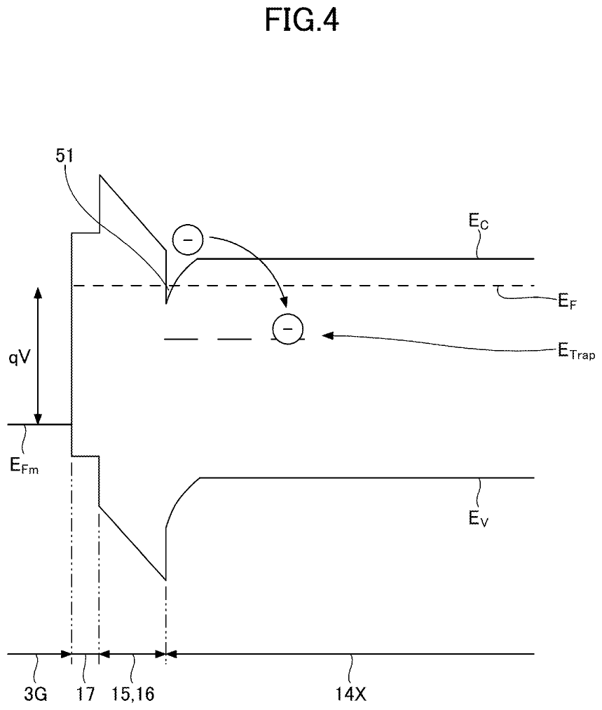

Here, a band structure of the buffer layer 12, the barrier layer 13, the electron traveling layer 14, the spacer layer 15, the electron supply layer 16, and the cap layer 17 will be described. FIG. 2 is a band diagram illustrating the band structure of the buffer layer 12, the barrier layer 13, the electron traveling layer 14, the spacer layer 15, the electron supply layer 16, and the cap layer 17 in the embodiment. FIG. 2 illustrates the band structure obtained when voltage V is applied to the gate electrode 3G. In FIG. 2, E_{Fm} is a Fermi level of the gate electrode 3G, E_{F} is a Fermi level of the stacked structure 20, E_{Trap} is a trap level in the electron traveling layer 14, E_{C} is the lower end of a conduction band, and E_{V} is the upper end of a valence band. The same applies to FIG. 4 described below.

As illustrated in FIG. 2, a region where the lower end E_{C} of the conduction band is lower than the Fermi level E_{F} is present near the upper surface of the electron traveling layer 14. In this region, two-dimensional electron gas (2DEG) 51 is present. Also, the band gap of the barrier layer 13 is larger than the band gap of the buffer layer 12 and the band gap of the electron traveling layer 14. Therefore, negative polarization charges (−σ) 52 are present near the interface between the barrier layer 13 and the electron traveling layer 14, and positive polarization charges (+σ) 53 are present near the interface between the barrier layer 13 and the buffer layer 12. Also, in the electron traveling layer 14, the lower end E_{C} of the conduction band is higher at a position closer to the barrier layer 13. Therefore, in the present embodiment, even if the electrons in the 2DEG 51 have high energy, the negative polarization charges 52 prevent movement of the electrons in the 2DEG 51 toward a deep position in the electron traveling layer 14. Therefore, even if the trap level E_{Trap} is present in the electron traveling layer 14, the electrons are not readily trapped at the trap level E_{Trap}, and transient response performance can be increased.

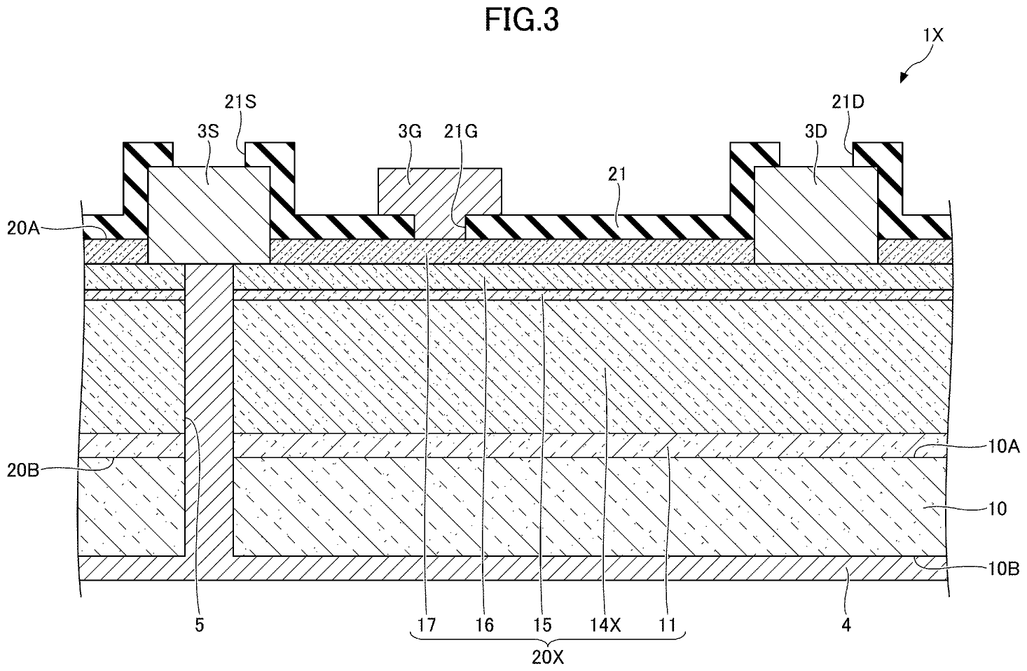

Next, a reference example will be described for comparison with the embodiment. FIG. 3 is a cross-sectional view illustrating a semiconductor device according to the reference example.

As illustrated in FIG. 3, a semiconductor device 1X according to the reference example includes a stacked structure 20X instead of the stacked structure 20. The stacked structure 20X includes an electron traveling layer 14X instead of the buffer layer 12, the barrier layer 13, and the electron traveling layer 14. The electron traveling layer 14X is, for example, an undoped GaN layer having a thickness of 400 nm. The configuration of the semiconductor device 1X is otherwise the same as the configuration of the semiconductor device 1.

Here, a band structure of the electron traveling layer 14X, the spacer layer 15, the electron supply layer 16, and the cap layer 17 will be described. FIG. 4 is a band diagram illustrating the band structure of the electron traveling layer 14X, the spacer layer 15, the electron supply layer 16, and the cap layer 17 in the reference example.

As illustrated in FIG. 4, similar to the embodiment, the 2DEG 51 is present in the reference example. However, because the barrier layer 13 is not provided, the negative polarization charges (−σ) 52 and the positive polarization charges (+σ) 53 are absent. Thus, the lower end E_{C} of the conduction band is constant in the electron traveling layer 14X. Therefore, when the electrons in the 2DEG 51 have high energy, the electrons in the 2DEG 51 tend to move toward a deep position in the electron traveling layer 14X, and to be trapped at the trap level E_{Trap} in the electron traveling layer 14X. Therefore, transient response performance can be degraded due to trapping of the electrons.

In this way, according to the present embodiment, by the presence of the barrier layer 13, the transient response performance can be increased compared to the transient response performance in the reference example. Also, because the transient response performance can be increased by the presence of the barrier layer 13, the buffer layer 12 does not need to be thin to an extent causing reduction in the crystallinity of the barrier layer 13, the electron traveling layer 14, the spacer layer 15, the electron supply layer 16, and the cap layer 17. Therefore, it is possible to increase transient response performance while avoiding reduction in crystallinity.

Moreover, because the buffer layer 12 may be relatively thick, the through-hole 5 is readily formed in a short time as described below. For formation of the through-hole 5, the stacked structure 20 is etched after etching of the substrate 10. Because the substrate 10 is much thicker than the stacked structure 20, it is preferable to perform etching of the substrate 10 at a high etching rate. However, if excessive over-etching is performed upon the etching of the substrate 10, the source electrode 3S may also be etched. Although lowering the etching rate can avoid such excessive over-etching, in this case, the formation of the through-hole 5 takes a longer time. With respect to the above, when the buffer layer 12 is relatively thick, etching of the source electrode 3S due to over-etching can be avoided. Therefore, the substrate 10 can be etched at a high etching rate, and the through-hole 5 is readily formed in a short time.

The barrier layer 13 may not be the AlN layer, and may be, for example, an AlₓIn_{y}Ga_{1-x-y}N layer (0<x≤1, 0≤y≤0.1). In this case as well, the band gap of the barrier layer 13 tends to be larger than the band gap of the buffer layer 12 and the band gap of the electron traveling layer 14. Note that, the composition of the AlₓIn_{y}Ga_{1-x-y}N layer may be a composition in which the polarization charges 52 and 53 equal to or more than in the case of using an AlₓGa₁₋ₓN layer (0.8≤x≤1) are obtained. For example, the relation of “y+0.8≤x” may be established. In this case, polarization charges 52 and 53 are more readily sufficiently obtained.

The thickness of the barrier layer 13 may be 2 nm or larger and 20 nm or smaller. When the thickness of the barrier layer 13 is 2 nm or larger, polarization charges are more readily sufficiently obtained. When the thickness of the barrier layer 13 is 20 nm or smaller, the barrier layer 13 is more readily pseudo-lattice matched with the buffer layer 12. The thickness of the barrier layer 13 may be 3 nm or larger and 18 nm or smaller and may be 5 nm or larger and 15 nm or smaller.

The barrier layer 13 may be an Al_{0.8}Ga_{0.2}N layer having a thickness of 3 nm.

The thickness of the buffer layer 12 may be 200 nm or larger. When the thickness of the buffer layer 12 is 200 nm or larger, favorable crystallinity is more readily obtained in the barrier layer 13, the electron traveling layer 14, the spacer layer 15, the electron supply layer 16, and the cap layer 17. The thickness of the buffer layer 12 may be 300 nm or larger or may be 400 nm or larger. The upper limit of the thickness of the buffer layer 12 may be 20 μm or smaller, may be 10 μm or smaller, or may be 1 μm or smaller. When the buffer layer 12 is too thick, it tends to take a longer time to form the buffer layer 12 and the through-hole 5.

The thickness of the electron traveling layer 14 may be 400 nm or smaller. When the thickness of the electron traveling layer 14 is 400 nm or smaller, the entirety of the electron traveling layer 14 is more readily influenced by the polarization charges 52. The thickness of the electron traveling layer 14 may be 350 nm or smaller or may be 300 nm or smaller. The lower limit of the thickness of the electron traveling layer 14 may be 200 nm or larger, may be 250 nm or larger, or may be 300 nm or larger. When the electron traveling layer 14 is too thin, the current flowing through the semiconductor device 1 tends to be reduced.

The electron traveling layer 14 is 400 nm and the thickness of the buffer layer 12 may be 400 nm or larger and 20 μm or smaller. In this case, compared to a configuration in which the buffer layer 12 and the barrier layer 13 are not provided, favorable crystallinity is more readily obtained in the electron traveling layer 14, the spacer layer 15, the electron supply layer 16, and the cap layer 17.

The thickness of the buffer layer 12 is 400 nm and the thickness of the electron traveling layer 14 may be 200 nm or larger and 400 nm or smaller. In this case, compared to the configuration in which the buffer layer 12 and the barrier layer 13 are not provided, movement of the electrons in the 2DEG 51 toward a deep position in the electron traveling layer 14 is more readily prevented. Also, by the presence of the polarization charges 52, a strong electric field is more readily applied to the entirety of the electron traveling layer 14. Therefore, transient response performance is more readily increased.

For example, the thickness of the buffer layer 12 may be greater than the thickness of the electron traveling layer 14 by a factor that is greater than 1 and that is less than or equal to 100.

While embodiments of the present disclosure have been described in detail, the present disclosure should not be construed as being limited to the specific embodiments. Various modifications and alterations are possible within the scope of claims as recited.

What is claimed is:

1. A semiconductor device, comprising:
a substrate;
a buffer layer above the substrate;
a barrier layer on the buffer layer;
an electron traveling layer on the barrier layer; and
an electron supply layer above the electron traveling layer, wherein
the electron traveling layer is thinner than the buffer layer, and
a band gap of the barrier layer is larger than a band gap of the buffer layer and a band gap of the electron traveling layer.

2. The semiconductor device according to claim 1, wherein
both of the buffer layer and the electron traveling layer are a GaN layer, and
the barrier layer is an AlₓIn_{y}Ga_{1-x-y}N layer (0<x≤1, 0≤y≤0.1).

3. The semiconductor device according to claim 2, wherein
a relation of “y+0.8≤x” is established.

4. The semiconductor device according to claim 1, wherein
a thickness of the barrier layer is 2 nm or larger and 20 nm or smaller.

5. The semiconductor device according to claim 1, wherein
a thickness of the buffer layer is 20 μm or smaller.

6. The semiconductor device according to claim 1, wherein
a thickness of the electron traveling layer is 200 nm or larger.
